(19) United States
(12) Patent Application Publication
(10) Pub. No.: US 2017/0246657 A1
(43) Pub. Date: Aug. 31, 2017

(54) IMPRINTING APPARATUS AND ARTICLE MANUFACTURING METHOD

(71) Applicant: CANON KABUSHIKI KAISHA, Tokyo (JP)

(72) Inventors: Wataru Tamura, Saitama-shi (JP); Noriyasu Hasegawa, Utsunomiya-shi (JP); Tosiya Asano, Utsunomiya-shi (JP); Setsuo Yoshida, Saitama-shi (JP)

(21) Appl. No.: 15/436,411

(22) Filed: Feb. 17, 2017

(30) Foreign Application Priority Data
Feb. 29, 2016 (JP) 2016-038127

(51) Int. Cl. B05D 3/12; H01L 21/027; H01L 21/67; B05C 11/02

(52) U.S. Cl. CPC B05D 3/12; B05C 11/02; H01L 21/0274; H01L 21/6715

(57) ABSTRACT

An imprinting apparatus can form a pattern of an imprint material supplied to a substrate with a mold. The imprinting apparatus includes a substrate holding unit configured to hold the substrate, a mold holding unit configured to hold the mold, and a control unit configured to control the mold holding unit that changes an inclination of the mold while the mold is kept in contact with the imprint material based on a position in a surface direction of the substrate where the mold contacts the imprint material, in such a way as to reduce a relative inclination between the mold and the substrate that may occur if the substrate holding unit inclines when the mold is brought into contact with the imprint material.

### BACKGROUND

Field

Aspects of the present invention generally relate to an imprinting apparatus and an article manufacturing method.

Description of the Related Art

An imprinting apparatus that can form a pattern of an imprint material supplied to a substrate with a mold is a prospective lithography apparatus employable in mass production of semiconductor devices or magnetic storage media. As discussed in Japanese Unexamined Patent Application Publication (Translation of PCT Application) No. 2008-522412, the imprinting apparatus performs a control for positioning the mold and the substrate in a state where the mold is kept in contact with the imprint material, to accurately overlay a shot region of the substrate with a pattern region of the mold. For example, the imprinting apparatus detects a mark provided for each of the pattern region and the shot region and performs the positioning control with reference to the detected marks in such a way as to keep a deviation of an actual relative position between the mold and the substrate from a target relative position within a permissible range.

The imprinting apparatus performs the control for positioning the mold and the substrate as mentioned above and hardens the imprint material in a state where the mold is kept in contact with the imprint material. Then, the imprinting apparatus separates the mold from the hardened imprint material to leave a pattern formed on the imprint material supplied to the substrate.

The imprinting apparatus generates a force to bring the mold into contact with the imprint material in the shot region. In this case, a stage that holds the substrate may incline if the applied force is inappropriate. If the stage inclines in the above-mentioned contact operation (i.e., in an imprinting operation), the mold will incline relative to the substrate. An operation for charging the imprint material to the pattern region of the mold may be undesirably performed in the state where the mold is inclined relative to the substrate and the imprint material may be hardened in the inclined state. If the above-mentioned operation for charging or hardening the imprint material is performed in the state where the mold is inclined relative to the substrate as mentioned above, there will be a risk of failing in the formation of a desired pattern on the substrate.

Further, the imprinting apparatus generates a force to separate the mold from the hardened imprint material. In this case, the stage that holds the substrate may incline in the process for separating the mold from the hardened imprint material. As a result, the mold may incline relative to the substrate. If the mold inclines relative to the substrate in the separating operation (i.e., a mold releasing operation), there will be a risk of damaging a pattern of the mold or a pattern formed on the imprint material.

### SUMMARY

According to an aspect of the present invention, an imprinting apparatus can form a pattern of an imprint material supplied to a substrate with a mold. The imprinting apparatus includes a substrate holding unit configured to hold the substrate, a mold holding unit configured to hold the mold, and a control unit configured to control the mold holding unit that changes an inclination of the mold while the mold is kept in contact with the imprint material based on a position in a surface direction of the substrate where the mold contacts the imprint material, in such a way as to reduce a relative inclination between the mold and the substrate that may occur if the substrate holding unit inclines in a process of bringing the mold into contact with the imprint material.

Further features of aspects of the present invention will become apparent from the following description of exemplary embodiments with reference to the attached drawings.

### BRIEF DESCRIPTION OF THE DRAWINGS

FIGS. 1A and 1B each schematically illustrate an imprinting apparatus according to a first exemplary embodiment.

FIGS. 2A and 2B illustrate an exemplary configuration of a substrate stage.

FIG. 3 is a flowchart illustrating an operation sequence of imprint processing to be performed in each of a plurality of shot regions.

FIGS. 4A and 4B each schematically illustrate a behavior of the substrate stage in a process for bringing a mold into contact with an imprint material.

FIG. 5 is a cross-sectional view of the substrate stage in the process for bringing the mold into contact with the imprint material.

FIG. 6 is a block diagram illustrating a control of inclination between the mold and the substrate, which can be performed by the imprinting apparatus according to the first exemplary embodiment.

FIGS. 7A and 7B each schematically illustrate a behavior of the substrate stage in a process for separating the mold from a hardened imprint material.

FIG. 8 schematically illustrates an imprinting apparatus according to a third exemplary embodiment.

FIGS. 9A, 9B, and 9C each illustrate shape differences between a pattern region and a target shot region.

### DESCRIPTION OF THE EMBODIMENTS

Hereinafter, exemplary embodiments of the present invention will be described with reference to attached drawings. In respective drawings, similar members or elements are denoted by the same reference numbers and redundant description thereof will be avoided.

An imprinting apparatus 100 according to a first exemplary embodiment of the present invention will be described in detail below. In the following description, it is assumed that the imprinting apparatus 100 moves a mold in such a way as to approach a substrate in a Z direction (i.e., a Z axis) and the substrate has a plane extending in an X axis an a Y axis that are perpendicular to the Z axis. The imprinting apparatus 100 is usable in the manufacturing of a semiconductor device and can perform imprint processing for forming a pattern of an imprint material 11 supplied to a target shot region of a substrate 3 with a mold 6. For example, the imprinting apparatus 100 causes the mold 6 to contact (or imprint) the imprint material 11 supplied to the target shot region and hardens the imprint material 11 in this state. Then, the imprinting apparatus 100 expands the clearance between the mold 6 and the substrate 3 to separate (or release) the mold 6 from the hardened imprint material 11. Through the above-mentioned imprint processing, the imprinting apparatus 100 can form an intended pattern of the imprint material 11 supplied to the target shot region. An exemplary method for hardening the imprint material 11 is a heat cycle method or a photo curing method. The method employed in the present exemplary embodiment is the photo curing method. The imprint material 11 used in the employed photo curing method is a photo-curable composition that hardens when irradiated with light. The photo curing method is characterized by irradiating the imprint material 11 with light (e.g., ultraviolet ray) to harden the imprint material 11 in a state where the mold 6 is in contact with the imprint material 11.

### [Apparatus Configuration]

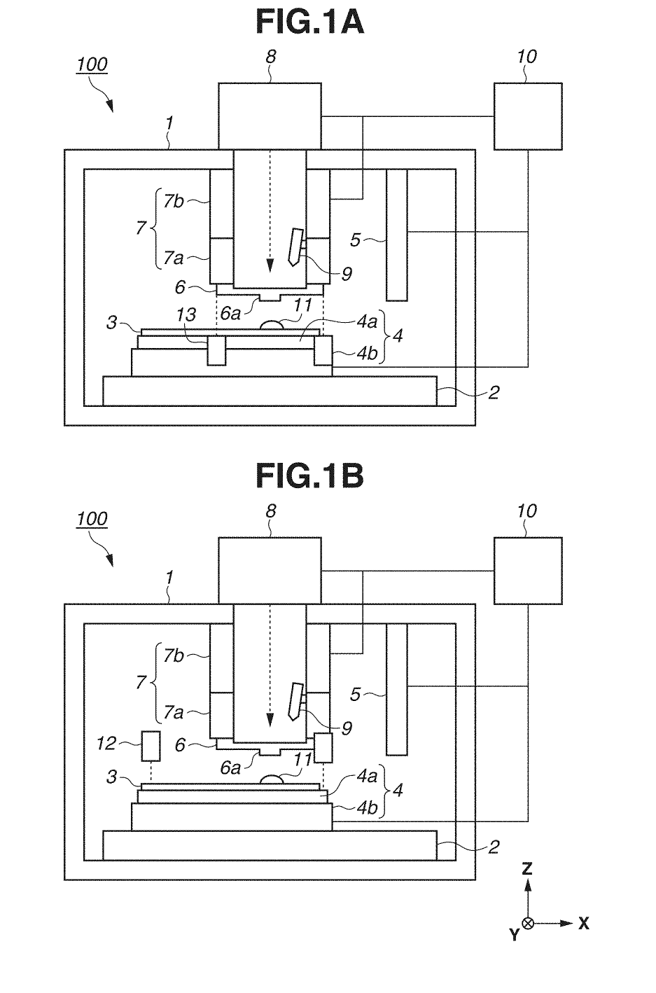

FIGS. 1A and 1B each schematically illustrate the imprinting apparatus 100 according to the first exemplary embodiment. The imprinting apparatus 100 includes an imprint head 7, a substrate stage 4, a hardening unit 8, a supply unit 5, a measurement unit 9, and a control unit 10. A structural body 1 supports each of the imprint head 7, the hardening unit 8, the supply unit 5, and the measurement unit 9. The substrate stage 4 is movable on a surface plate 2. For example, the control unit 10 includes a central processing unit (CPU) and a memory. The control unit 10 can control the imprint processing by controlling operations of respective units of the imprinting apparatus 100.

The mold 6 (e.g., a die or a template) is made of a material (e.g., quartz) capable of transmitting an ultraviolet ray. The mold 6 has a concave-convex shaped pattern (i.e., a pattern region 6a), which is partly formed on a face opposed to the substrate, to deform the imprint material 11 into a desired shape. The substrate 3 is, for example, made of a single crystal silicon substrate or a glass substrate. The supply unit 5 supplies the imprint material 11 to an upper surface (i.e., a surface to be processed) of the substrate 3.

The hardening unit 8 irradiates the imprint material 11, via the mold 6, with light (e.g., ultraviolet ray) that can harden the imprint material 11. For example, the hardening unit 8 can include a light source that emits light capable of hardening the imprint material 11 and an optical element that appropriately adjusts the light emitted from the light source. Because the method employed in the first exemplary embodiment is the photo curing method, the light source capable of emitting the ultraviolet ray is provided in the hardening unit 8. However, for example, if the employed method is the heat cycle method, the light source is replaced by a heat source capable of hardening a thermosetting composition (i.e., the imprint material 11).

The imprint material 11 is a curable composition and is typically a composition that hardens when irradiated with light or heated. The photo-curable composition (i.e., the composition that hardens when irradiated with light) can contain at least a polymerizable compound and a photopolymerization initiator. Further, the photo-curable composition can additionally contain a non-polymerizable compound or a solvent. For example, the non-polymerizable compound can be selected from the groups consisted of sensitizer, hydrogen donor, internal mold release agent, surface active agent, antioxidant, and polymer component.

The measurement unit 9 can detect an alignment mark formed on the mold 6 (i.e., the pattern region 6a) and an alignment mark provided on the substrate 3 (i.e., the shot region). The imprinting apparatus can measure a relative position (i.e., a positional deviation) between the pattern region 6a and the shot region based on a relative position of the alignment marks detected by the measurement unit 9. Further, the imprinting apparatus can measure a shape difference between the pattern region 6a and shot region by detecting a plurality of alignment marks.

The supply unit 5 can supply (apply) the imprint material 11 to the shot region of the substrate 3. The imprinting apparatus 100 according to the first exemplary embodiment supplies the imprint material 11, which hardens when irradiated with the ultraviolet ray, to the shot region.

For example, the imprint head 7 (i.e., a mold holding unit) includes a mold holding unit 7a configured to hold the mold 6 with a vacuum suction force or an electrostatic force and a mold drive unit 7b configured to drive the mold holding unit 7a in the Z direction. Each of the mold holding unit 7a and the mold drive unit 7b has a corresponding aperture region provided at the center thereof. The light from the hardening unit 8 can travel toward the substrate 3 via the aperture regions of the mold holding unit 7a and the mold drive unit 7b. In other words, the hardening unit 8 can irradiate the imprint material 11 supplied to the substrate 3 with the light that travels via the aperture regions of the imprint head 7 and passes through the mold 6. The mold drive unit 7b has a function of driving the mold 6 in the Z direction and an adjustment function of adjusting the position of the mold 6 in XY directions and a 8 direction (i.e., a rotational direction around the Z axis). Further, the mold drive unit 7b has a tilt function of changing the inclination of the mold 6 (i.e., the position of the mold in a rotational direction around the X axis or the Y axis).

For example, the substrate stage 4 (i.e., a substrate holding unit) includes a substrate chuck 4a capable of holding the substrate 3 with a vacuum suction force or an electrostatic force and a substrate drive unit 4b configured to mechanically hold the substrate chuck 4a and move on the surface plate 2. The substrate stage 4 can perform a positioning for the substrate 3 in the XY directions. In addition to the function of moving the substrate 3 in the XY directions, the substrate stage 4 may have an adjustment function of adjusting the position of the substrate 3 in the Z direction and the 8 direction and a tilt function of correcting the inclination of the substrate 3.

In the first exemplary embodiment, the substrate stage 4 is configured to be movable in the XY directions (i.e., a plane direction) to change a relative position between the mold 6 and the substrate 3. Alternatively, only the imprint head 7 can be configured to be movable in the XY directions. Further, as another example, both of the substrate stage 4 and the imprint head 7 can be configured to be movable in the XY directions. Similarly, in the first exemplary embodiment, the imprint head 7 is configured to be movable to change the clearance between the mold 6 and the substrate 3 (i.e., the distance in the Z direction). Alternatively, only the substrate stage 4 or both of the imprint head 7 and the substrate stage 4 can be configured to be movable in the Z direction.

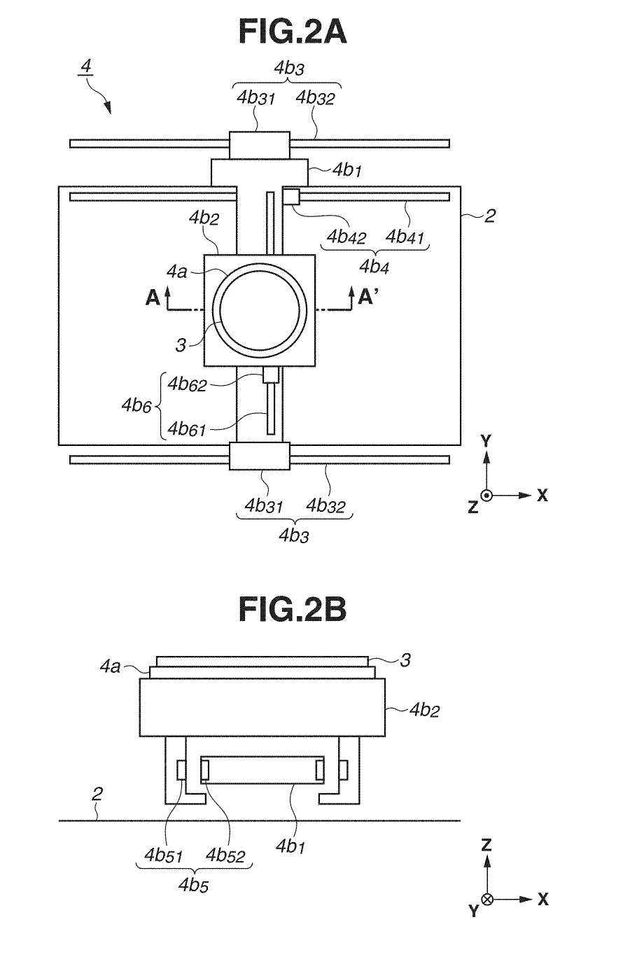

Hereinafter, an exemplary configuration of the substrate stage 4 will be described in detail below with reference to FIGS. 2A and 2B. FIGS. 2A and 2B illustrate an exemplary configuration of the substrate stage 4. FIG. 2A illustrates the substrate stage 4 seen from the Z direction. FIG. 2B is a cross-sectional view taken along a line A-A′ illustrated in FIG. 2A. For example, the substrate drive unit 4b of the substrate stage 4 includes an X stage 4b1 (i.e., a first stage) and a Y stage 4b2 (i.e., a second stage). The X stage 4b1 is movable in a first direction (e.g., the X direction) on the surface plate 2. Further, the Y stage 4b2 supports the substrate chuck 4a. A hydrostatic guide (not illustrated) can move the Y stage 4b2 in a second direction (e.g., the Y direction), which is different from the first direction, on the X stage 4b1. The substrate drive unit 4b having the above-mentioned configuration can move the Y stage 4b2 and the substrate chuck 4a (i.e., the substrate 3) in the X direction by driving the X stage 4b1 in the X direction. Further, the substrate drive unit 4b can move the substrate chuck 4a (i.e., the substrate 3) in the Y direction by driving the Y stage 4b2 in the Y direction. More specifically, the substrate drive unit 4b can move the substrate 3 in the XY directions by driving the X stage 4b1 in the X direction and driving the Y stage 4b2 in the Y direction.

The X stage 4b1 is positioned by the hydrostatic guide in such a way as to keep a predetermined amount of clearance between the X stage 4b1 and the surface plate 2. The X stage 4b1 can move in the X direction on the surface plate 2 when a first drive unit 4b3 drives the X stage 4b1. For example, the first drive unit 4b3 can include a linear motor, which is constituted by a mover 4b31 including a permanent magnet and a stator 4b32 including a plurality of coils disposed in the X direction. The first drive unit 4b3 can control the current to be supplied to the plurality of coils of the stator 4b32 and can move the X stage 4b1 in the X direction by causing the mover 4b31 to move along the stator 4b32. A first detection unit 4b4, which is configured by for example an encoder or an interferometer, can detect the position of the X stage 4b1 in the X direction. The first detection unit 4b4 illustrated in FIG. 2A is an encoder that includes a scale 4b41 that can emit light and a head 4b42 that can detect the position of the X stage 4b1 in the X direction with reference to the light from the scale 4b41.

Further, the Y stage 4b2 is positioned by the hydrostatic guide in such a way as to keep a predetermined amount of clearance between the Y stage 4b2 and the X stage 4b1. The Y stage 4b2 can move in the Y direction on the X stage 4b1 when a second drive unit 4b5 drives the Y stage 4b2. For example, the second drive unit 4b5 can include a linear motor, which is constituted by a mover 4b51 including a permanent magnet and a stator 4b52 including a plurality of coils disposed in the Y direction, as illustrated in FIG. 2B. The second drive unit 4b5 can control the current to be supplied to the plurality of coils of the stator 4b52 and can move the Y stage 4b2 to in the Y direction by causing the mover 4b51 to move along the stator 4b52. A second detection unit 4b6, which is configured by for example an encoder or an interferometer, can detect the position of the Y stage 4b2 in the Y direction. The second detection unit 4b6 illustrated in FIG. 2A is an encoder that includes a scale 4b61 that can emit light and a head 4b62 that can detect the position of the Y stage 4b2 in the Y direction with reference to the light from the scale 4b61.

Further, the imprinting apparatus 100 can include a plurality of measurement devices (not illustrated) that can measure the height of the X stage 4b1 and the height of the Y stage 4b2. For example, if a plurality of height measurement devices is provided on the surface plate 2, it will be feasible to measure an inclination of the X stage 4b1 and an inclination of the Y stage 4b2 relative to the surface plate 2.

### [Imprint Processing in Each Shot Region]

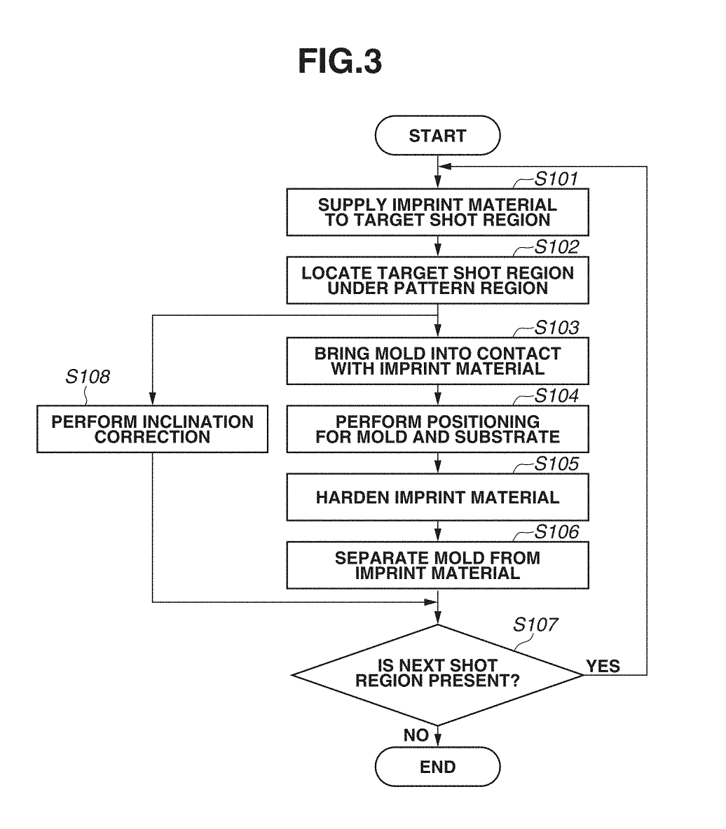

Next, an exemplary operation of the imprinting apparatus that forms a pattern of an imprint material at each of a plurality of shot regions on the substrate 3 will be described in detail below with reference to FIG. 3. FIG. 3 is a flowchart illustrating an operation sequence of the imprint processing. The imprinting apparatus can form patterns at the plurality of shot regions by performing the imprint processing at the respective shot regions.

In step S101, the control unit 10 controls the substrate stage 4 in such a way as to locate a shot region where a target pattern should be formed (hereinafter, referred to as “target shot region 3a”) under the supply unit 5. Then, the supply unit 5 supplies the imprint material 11 to the target shot region 3a. Alternatively, the operation for supplying the imprint material 11 to the target shot region 3a can be performed without changing a positional relationship between the target shot region 3a and the supply unit 5, or changing the relative position between the target shot region 3a and the supply unit 5.

In step S102, the control unit 10 controls the substrate stage 4 in such a way as to locate the target shot region 3a under the mold 6 (i.e., the pattern region 6a). In step S103, the control unit 10 controls the imprint head 7 in such a way as to reduce the clearance between the mold 6 and the substrate 3 to bring the mold 6 into contact with the imprint material 11 in the target shot region 3a. Then, the control unit 10 causes the mold drive unit 7b of the imprint head 7 to generate a force for causing the mold 6 to contact the imprint material 11 in such a manner that a concave-convex pattern formed in the pattern region 6a is filled with the imprint material 11. The force for causing the mold 6 to contact the imprint material 11 is, for example, a force for pressing the mold 6 against the imprint material 11 and is hereinafter referred to as “imprint force”. The control unit 10 can release the imprint force if a predetermined time has elapsed in a state where the mold drive unit 7b continuously generates the imprint force. In this case, it is unnecessary to completely decrease the imprint force to zero. A small amount of imprint force will be acceptable even if it remains. Further, it is feasible to generate a smaller force expanding the clearance between the mold 6 and the substrate 3. In a state where the mold 6 is in contact with the imprint material 11, the mold 6 may not be surely released from the imprint material 11 even when the tiny force acts in a clearance expanding direction because a capillary phenomenon will generate a force acting in such a way as to decrease the clearance between the mold 6 and the substrate 3.

In step S104, the imprinting apparatus performs positioning for the mold 6 and the substrate 3. For example, the control unit 10 causes the measurement unit 9 to detect the alignment marks formed on the mold 6 and the substrate 3 and measures a relative position between the pattern region 6a and the target shot region 3a based on the detected alignment marks. Then, the control unit 10 performs a feedback control for adjusting the relative position between the mold 6 and the substrate 3 in such a way as to keep a deviation of the relative position measured by the measurement unit 9 from a target relative position within a permissible range.

In step S105, the control unit 10 controls the hardening unit 8 in such a way as to emit light (e.g., ultraviolet ray) in a state where the mold 6 is in contact with the imprint material 11. The imprint material 11 hardens when it is irradiated with the light. In step S106, the control unit 10 controls at least one of the imprint head 7 and the substrate stage 4 in such a way as to increase the clearance between the mold 6 and the substrate 3. Thus, the mold 6 can be separated (released) from the hardened imprint material 11. In step S107, the control unit 10 determines whether there is a shot region in which a pattern should be formed (i.e., the next shot region) on the substrate. If it is determined that the next shot region is present (Yes in step S107), the operation returns to step S101 in which the control unit 10 performs the imprint processing again. If it is determined that the next shot region is not present (No in step S107), the control unit 10 terminates the imprint processing.

In step S108, the imprinting apparatus 100 according to the present invention corrects the relative inclination between the mold 6 and the substrate 3 that may occur if the substrate stage inclines in the above-mentioned sequential processes continuing from the contact in step S103 to the separation in step S106. An exemplary method for correcting the relative inclination between the mold 6 and the substrate 3 will be described in detail below.

### [Relative Inclination Between Mold and Substrate]

The imprint force generated by the imprinting apparatus 100 causes the substrate stage 4 (i.e., the Y stage 4b2) to incline in a process for bringing the mold 6 into contact with the imprint material 11 (see step S103). If the substrate stage 4 inclines, the substrate 3 may incline relative to the mold 6 (e.g., in a 8Y direction around the Y axis).

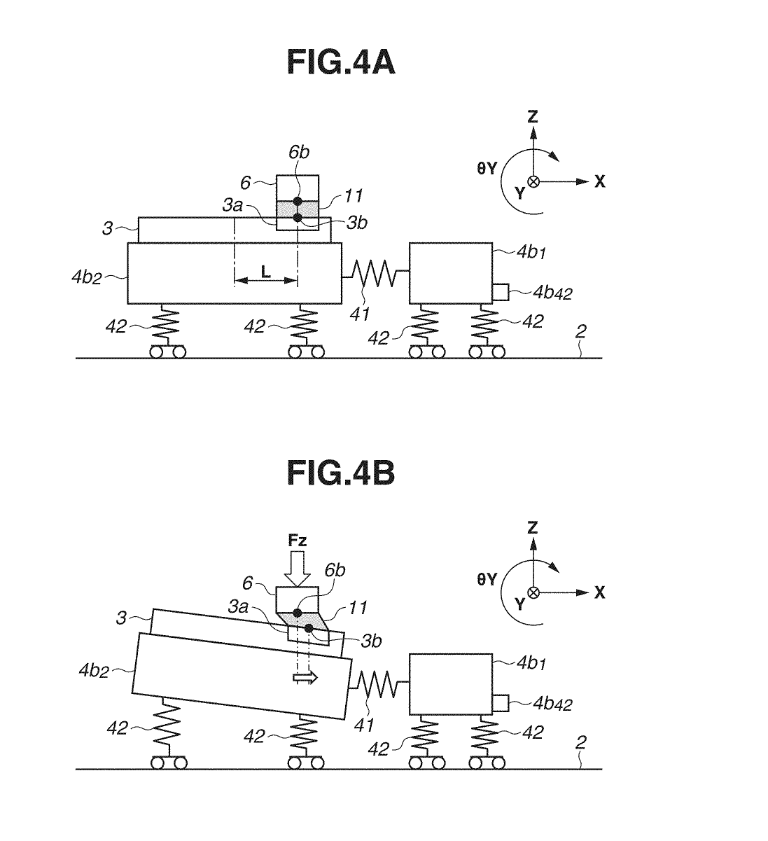

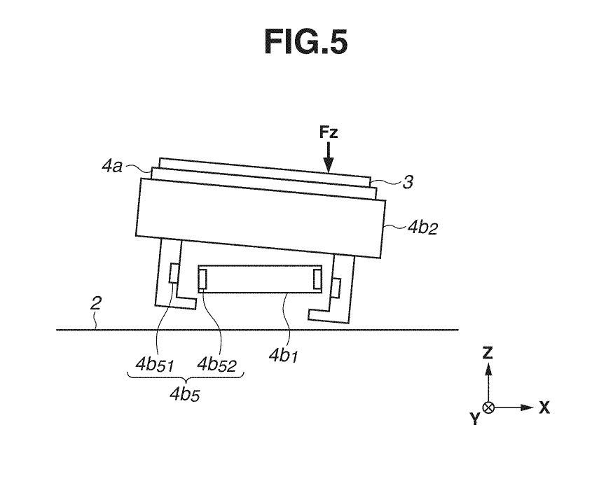

The behavior of the substrate stage 4 that causes the mold 6 to contact the imprint material 11 will be described in detail below with reference to FIGS. 4A and 4B and FIG. 5. FIGS. 4A and 4B schematically illustrate an exemplary behavior of the substrate stage 4 in the process for causing the mold 6 to contact the imprint material 11. To simplify the description, the schematic view of the substrate stage 4 illustrated in FIGS. 4A and 4B includes a hydrostatic guide 41 expressed as a spring element. The hydrostatic guide 41 connects the X stage 4b1 and the Y stage 4b2, which are arrayed in the horizontal direction. The hydrostatic guide 41 is a mechanism capable of supporting the substrate stage 4 with pressurized fluid, such as high-pressure lubricating oil or compressed air, and can realize higher positioning accuracy. Each hydrostatic guide 42 provided on the surface plate 2 is expressed as a combination of a spring element and wheels. In other words, the hydrostatic guide 42 has elasticity in the Z direction only and is freely movable in the XY directions. FIG. 5 is a cross-sectional view illustrating the substrate stage 4 in the process for bringing the mold 6 into contact with the imprint material 11 (i.e., a cross-sectional view taken along the line A-A′ illustrated in FIG. 2A).

For example, as illustrated in FIG. 4A, it is assumed that the target shot region 3a is offset from a reference position of the substrate 3 (e.g., the center) by a distance L in the +X direction. In FIG. 4A, to facilitate the understanding, it is assumed that there is no initial positional deviation between a mark 3b of the target shot region 3a and a mark 6b of the mold 6 in the X direction. In this case, if an imprint force Fz is applied to the imprint material 11 in the state illustrated in FIG. 4A, as illustrated in FIG. 4B and FIG. 5, the applied imprint force Fz causes the Y stage 4b2 to incline in the 8Y direction (i.e., a rotational direction around the Y axis). As a result, even when a feedback control for adjusting the position of the X stage 4b1 in the X direction is performed based on a detection result obtained by the first detection unit 4b4, the mark 3b of the target shot region 3a and the mark 6b of the mold 6 can relatively shift in the X direction. More specifically, the relative position between the mold 6 and the target shot region 3a deviates in the X direction. The imprint material 11 in this state (i.e., the imprint material 11 not yet hardened) possesses both of elasticity and viscosity characteristics (i.e., viscoelasticity characteristics).

Therefore, due to the elasticity of the imprint material 11, a force acting in the −X direction is applied from the imprint material 11 to the target shot region 3a (i.e., the substrate 3). More specifically, a force for causing a deviation in relative position acts on the mold 6 and the substrate 3. However, because the position of the X stage 4b1 is controlled based on the detection result obtained by the first detection unit 4b4, the hydrostatic guide 41 is in an expanded state. Accordingly, even if the imprint force Fz is removed to return the inclination of the Y stage 4b2 to the original state, the relative position between the mold 6 and the target shot region 3a can change slowly due to viscosity of the imprint material 11. Therefore, a significant time is required until the relative position between the mold 6 and the target shot region 3a settles.

Further, if the substrate stage 4 (i.e., the substrate drive unit 4b) inclines in the process for bringing the mold 6 into contact with the imprint material 11, the substrate 3 may incline relative to the mold 6. If the mold 6 inclines relative to the substrate 3, the pattern region 6a does not become parallel to the target shot region 3a. In this case, the concave-convex pattern of the mold 6 is filled with the imprint material 11 in the state where the pattern region 6a is inclined relative to the target shot region 3a. When the concave-convex pattern of the mold 6 is filled with the imprint material 11 in the state where the mold 6 is inclined relative to the substrate 3, there is a risk that the distribution of the imprint material 11 does not become uniform in the pattern region 6a and a significant time is required to complete the charging operation. Further, if the mold 6 inclines relative to the substrate 3, a shape difference between the pattern region 6a and the target shot region 3a may be caused. Even when the substrate stage 4 returns to the original (i.e., parallel) position after the substrate stage 4 inclines in the imprinting operation, there is a risk of deteriorating the accuracy in positioning the target shot region 3a and the pattern region 6a (namely, causing the shape difference) due to the viscoelasticity of the imprint material 11.

Further, if the imprint force is applied to the substrate 3 and the mold 6 in the state where the mold 6 is inclined relative to the substrate 3, the imprint processing will be performed in a state where the clearance between a part of the mold 6 and the substrate 3 is locally narrowed (e.g., in a contact state). If the imprint force is continuously applied between the substrate 3 and the mold 6 in the above-mentioned state, there will be a risk of damaging the substrate 3 or the mold 6. Further, when the imprinting apparatus separates the mold 6 from the imprint material in the state where the mold 6 is inclined relative to the substrate 3, there is a risk of damaging the pattern of the imprint material 11 formed on the substrate 3 because a force acts in the XY directions perpendicular to the Z direction (i.e., the separation direction).

### [Control of Relative Inclination Between Mold and Substrate]

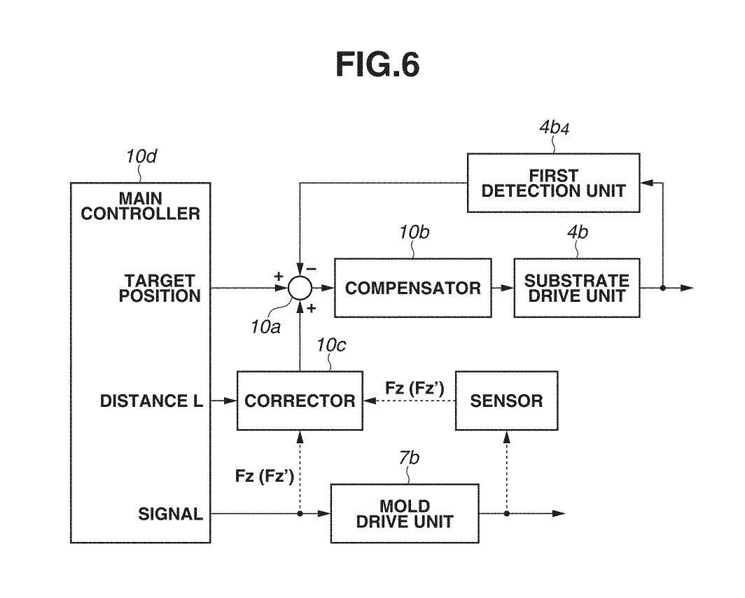

Next, an exemplary control of the relative inclination between the mold 6 and the substrate 3 that can be performed by the imprinting apparatus 100 according to the first exemplary embodiment will be described with reference to FIG. 6. FIG. 6 is a block diagram illustrating the control of the inclination between the mold 6 and the substrate 3, which can be performed by the imprinting apparatus 100 according to the first exemplary embodiment. The control unit 10 includes a subtracter 10a, a compensator 10b, a corrector 10c, and a main controller 10d illustrated in FIG. 6.

The imprinting apparatus 100 according to the first exemplary embodiment controls the inclination of the imprint head 7 in such a way as to reduce the relative inclination between the mold 6 and the substrate 3, which occurs when the substrate stage 4 inclines in the process for bringing the mold 6 into contact with the imprint material 11. The mold drive unit 7b, which is configured to change the inclination of the mold holding unit 7a, controls the relative inclination between the substrate 3 and the mold 6 (in the rotational direction around the X axis or the Y axis). For example, the mold drive unit 7b includes a plurality of actuators. The mold drive unit 7b can press the mold 6 against the imprint material 11 by cooperatively driving the mold 6 in the Z direction and can intentionally incline the mold 6 by differentiating the outputs of respective actuators. The substrate drive unit 4b is configured to drive the substrate 3 in the Z direction so that the imprint material 11 located on the substrate 3 can contact the mold 6 and is also configured to incline the substrate 3.

More specifically, the mold drive unit 7b adjusts the inclination of the mold 6 according to the inclination of the substrate stage 4 when the operation for bringing the mold 6 into contact the imprint material 11 is completed. The mold drive unit 7b adjusts the inclination of the mold holding unit 7a in such a way as to reduce the relative inclination between the mold 6 and the substrate 3 that may occur when the substrate stage 4 inclines. When the mold drive unit 7b adjusts the inclination of the mold holding unit 7a, it is desired to bring the mold 6 (more specifically, the pattern region 6a) into a parallel relationship with the substrate 3 (more specifically, the target shot region 3a) in the state where the mold 6 is kept in contact with the imprint material 11. More specifically, it is desired that the thickness of a residual pattern film of the imprint material 11 formed on the substrate 3 becomes uniform. The residual film of the imprint material 11 is a filmy imprint material between the substrate 3 and a recessed portion of a concave-convex pattern constituted by the imprint material 11, which may be referred to as “residual layer thickness (RLT)”. The above-mentioned adjustment of the relative inclination between the mold 6 and the substrate 3 can be performed by the substrate drive unit 4b or can be performed by drive of both of the substrate drive unit 4b and the mold drive unit 7b.

The relative inclination between the mold 6 and the substrate 3 can be controlled with reference to the imprint force Fz and the distance L from the reference position of the substrate 3 to the target shot region 3a. In this case, it is desired that the reference position is a specific position (e.g., the center of the substrate 3) where the inclination of the substrate stage 4 is relatively smaller when the mold 6 is brought into contact with the imprint material 11. For example, the centroid of the substrate 3 can be set as the reference position.

The relative inclination between the mold 6 and the substrate 3 during an imprinting operation is proportional to the imprint force Fz and the distance L from the reference position of the substrate 3 to the target shot region 3a. Therefore, the corrector 10c can obtain a target amount (i.e., a correction value) with respect to the inclination between the mold 6 and the substrate 3 in an imprinting operation with reference to information (e.g., a calculation formula or a table) indicating the relative inclination between the mold 6 and the substrate 3 in relation to the imprint force Fz and the distance L. The information indicating the inclination amount in relation to the imprint force Fz and the distance L can be acquired beforehand through simulations and experiments. Further, it is feasible to acquire a relationship between the imprinting position and the inclination amount with reference to a result obtainable when a pattern is formed on another substrate 3. Further, the relationship between the imprinting position and the inclination amount is correctable.

Further, if the mold 6 is configured to be a convex shape relative to the substrate 3, the imprinting apparatus 100 can cause the mold 6 to contact the imprint material 11 in such a way as to gradually increase the contact area. In this case, the relative inclination between the substrate 3 and the mold 6 can be regarded as the inclination between the substrate stage 4 and the imprint head 7. The adjustment of the relative inclination between the substrate 3 and the mold 6 can be performed by adjusting the relative inclination between the substrate stage 4 and the imprint head 7. In a case where the surface of the substrate 3 is not parallel to the XY plane, it is desired to incline the mold holding unit 7a in accordance with the inclination of the target shot region 3a in the process for bringing the mold 6 into contact with the imprint material 11. Subsequently, the mold holding unit 7a adjusts the inclination of the mold 6 based on the inclination amount of the substrate stage 4 that is acquirable at each position on the substrate 3.

Further, the imprinting apparatus 100 can adjust the inclination of the imprint head 7 based on a detection result of the inclination of the substrate stage 4. For example, to measure the relative inclination between the mold 6 and the substrate 3, the imprinting apparatus 100 includes a substrate measurement unit 12 (see FIG. 1A) configured to measure the inclination of the surface of the substrate 3 and a mold measurement unit 13 (see FIG. 1B) configured to measure the inclination of the pattern region 6a of the mold 6.

The substrate measurement unit 12 can measure the inclination of the surface of the substrate 3 at a position where the mold 6 contacts the imprint material 11 located on the substrate 3. The substrate measurement unit 12 includes a height sensor (i.e., a gap sensor) that can measure the height of the surface of the substrate 3 (in the Z direction) at each of a plurality of spots. The substrate measurement unit 12 can obtain an inclination amount of the substrate 3 with reference to information about a plurality of heights on the surface of the substrate 3. For example, the substrate measurement unit 12 can include a laser interferometer configured to irradiate the surface of the substrate 3 with light (e.g., laser beam) at a plurality of spots to measure the height of the surface of the substrate 3.

The mold measurement unit 13 can measure the inclination of the surface of the mold 6 at a position where the mold 6 is brought into contact with the imprint material 11 located on the substrate 3. The mold measurement unit 13 includes a height sensor (e.g., a gap sensor) that can measure the height of the pattern region 6a of the mold 6 (in the Z direction) at a plurality of spots. The mold measurement unit 13 can obtain an inclination amount of the mold 6 with reference to information about a plurality of heights on the surface of the mold 6. For example, the mold measurement unit 13 can include a laser interferometer configured to irradiate the surface of the mold 6 with light (e.g., laser beam) at a plurality of spots to measure the height of the surface of the mold 6. The surface of the mold 6 can be the pattern region 6a on which a pattern is formed or its reverse surface.

Further, as mentioned above, it is feasible to acquire the inclination amount of the substrate stage 4 with reference to the measurement result obtained by the measurement device (i.e., the substrate measurement unit) that can measure the height of the substrate stage 4 provided on the surface plate 2.

Next, an exemplary method for adjusting (correcting) the relative inclination between the mold 6 and the substrate 3 (see step S108 in FIG. 3) will be described in detail below. In step S103 illustrated in FIG. 3, the substrate stage 4 inclines because the pattern region 6a of the mold 6 is brought into contact with the imprint material 11 and the imprint force is applied to the substrate stage 4. Therefore, in parallel with the processing in step S103, the control unit 10 adjusts the inclination of the mold holding unit 7a with reference to a relationship between the inclination amount and the position on the substrate 3, which can be obtained beforehand. Further, in a case where the substrate measurement unit 12 can measure the inclination amount of the substrate stage 4, the control unit 10 adjusts the inclination of the mold holding unit 7a based on an acquired measurement result. The mold measurement unit 13 can be used to measure the inclination of the mold 6.

The control unit 10 obtains a relative inclination amount between the substrate 3 and the mold 6 based on two inclination amounts measured by the substrate measurement unit 12 and the mold measurement unit 13. Then, the control unit 10 drives at least one of the mold drive unit 7b and the substrate drive unit 4b based on the obtained inclination amount, in such a way as to reduce the inclination amount between the target shot region 3a and the pattern region 6a, until the mold releasing operation through steps S103 to S106 illustrated in FIG. 3 completes. More specifically, the control unit 10 adjusts the relative inclination between the mold 6 and the substrate 3 in such a way as to place the pattern region 6a in parallel with the target shot region 3a after the mold 6 is brought into contact with the imprint material 11. When a predetermined time has elapsed in a state where the mold drive unit 7b generates the imprint force, the control unit 10 may decrease the imprint force to be generated by the mold drive unit 7b in the positioning processing of step S104. Therefore, if the imprint force changes, the relative inclination between the substrate 3 and the mold 6 will change correspondingly. In this respect, it is desired to measure the inclination amount before the mold releasing operation completes.

Further, the control unit 10 can adjust the relative inclination between the substrate 3 and the mold 6 with reference to an inclination correction value obtained beforehand and a measurement result of the inclination amount of the substrate stage 4. The subtracter 10a adds the correction value to a deviation between the present inclination of the mold drive unit 7b and a target inclination amount. The compensator 10b determines a command value to tilt drive the mold drive unit 7b based on the value obtained by adding the correction value to the deviation. As mentioned above, it is feasible to perform a feedback control for correcting the inclination amount of the imprint head 7 (i.e., the mold 6) based on a measurement result of the inclination of the substrate stage 4 (i.e., the surface of the substrate 3) after the mold 6 is brought into contact with the imprint material 11.

The imprinting apparatus 100 according to the first exemplary embodiment controls the relative inclination between the substrate 3 and the mold 6 in the state where the mold 6 is kept in contact with the imprint material 11. Therefore, the imprinting apparatus 100 according to the first exemplary embodiment can reduce the relative inclination between the substrate 3 and the mold 6, which may occur when the substrate stage 4 inclines.

The above-mentioned imprint force Fz can be obtained, for example, by multiplying a value of a signal to be supplied to the mold drive unit 7b with a thrust constant indicating a force that the mold drive unit 7b generates when a unit amount of signal value is supplied. Further, if a sensor (e.g., a force sensor, a load cell, or a strain gauge) is provided to detect a force generated by the mold drive unit 7b, it is feasible to obtain the imprint force Fz based on a detection result obtained by the sensor.

As mentioned above, the imprinting apparatus 100 according to the first exemplary embodiment controls the relative inclination between the mold 6 and the substrate 3 based on the imprint force Fz and the distance L in the process for causing the mold 6 to contact the imprint material 11. In a case where a plurality of target shot regions 3a is provided on the substrate 3, it is useful to acquire an inclination amount (i.e., a correction value) corresponding to each place of the target shot region 3a beforehand (instead of referring to the distance L) as the information indicating the above-mentioned inclination relationship. More specifically, the imprinting apparatus 100 determines an inclination amount (i.e., a correction value) corresponding to a designated coordinate position on the substrate 3. Thus, the imprinting apparatus 100 can reduce the relative inclination between the mold 6 and the substrate 3 that may occur if the substrate stage 4 inclines in the process for bringing the mold 6 into contact with the imprint material 11. More specifically, the imprinting apparatus 100 can perform imprint material charging and positioning operations after completing the imprinting operation, in a state where the pattern region 6a of the mold 6 is located in parallel with the target shot region 3a of the substrate 3. The time required to charge the imprint material in the pattern region 6a can be reduced. As a result, the throughput can be improved.

A second exemplary embodiment will be described in detail below. The imprinting apparatus 100 causes the mold drive unit 7b of the imprint head 7 to generate the force for separating the mold 6 from the hardened imprint material 11 in the process for separating (or releasing) the mold 6 from the hardened imprint material 11 (step S106). In this case, the separation force may cause the substrate stage 4 to incline in the process of step S106. If the substrate stage 4 inclines, the substrate 3 inclines correspondingly relative to the mold 6. In this case, the separation force is a force required to separate the mold 6 from the hardened imprint material 11 and is opposed to the imprint force. The separation force can be referred to as “mold releasing force”.

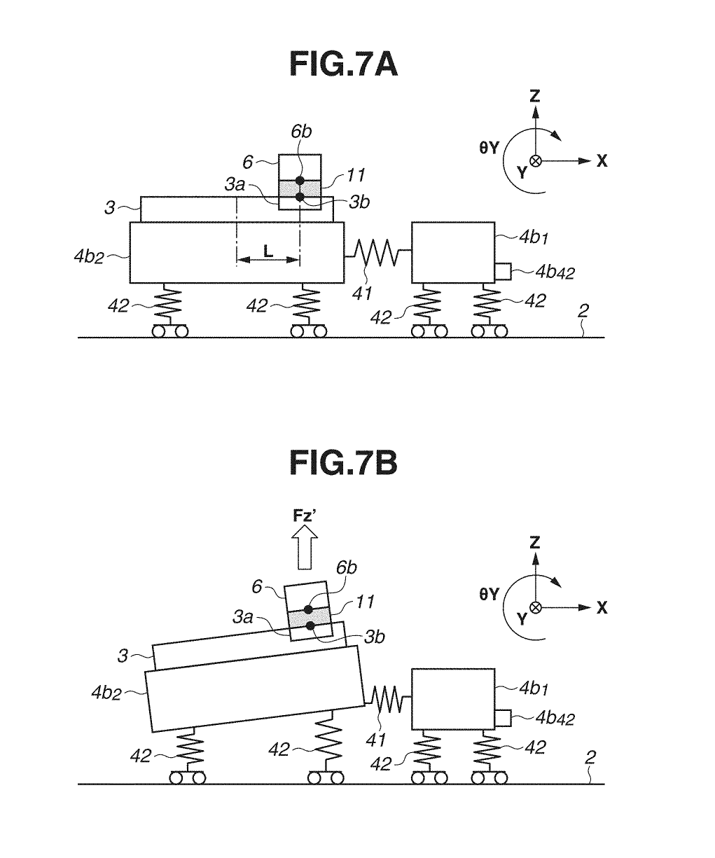

FIGS. 7A and 7B schematically illustrate a behavior of the substrate stage 4 in the process for separating the mold 6 from the hardened imprint material 11. FIG. 7A illustrates an exemplary state of the substrate stage 4 immediately after the imprint material 11 is hardened. FIG. 7B illustrates an exemplary state of the substrate stage 4 immediately before the separation force Fz′ acts to start the operation for separating the mold 6 from the hardened imprint material 11. In FIG. 7B, the substrate stage 4 (i.e., the Y stage 4b2) inclines due to the applied separation force Fz′. In the state where the substrate 3 is inclined relative to the mold 6, a force for causing the pattern to incline relative to the mold 6 and the imprint material 11, on which the pattern is formed, acts in the XY directions. As a result, there is a risk of damaging the pattern of the mold 6 or the pattern of the imprint material 11.

In view of the above, the imprinting apparatus according to the second exemplary embodiment controls the inclination of the imprint head 7 in such a way as to reduce the relative inclination between the mold 6 and the substrate 3 that may occur when the substrate stage 4 inclines in the process for separating the mold 6 from the imprint material 11. The relative inclination between the mold 6 and the substrate 3 can be controlled based on the separation force Fz′ and the distance L from the reference position of the substrate 3 to the target shot region 3a.

In the second exemplary embodiment, the control unit 10 performs processing in step S106 that is similar to the processing performed in step S103. More specifically, the corrector 10c corrects the relative inclination between the mold 6 and the substrate 3 that may occur when the substrate stage 4 inclines. More specifically, the control unit 10 inclines the imprint head 7 in such a way as to reduce the relative inclination between the mold 6 and the substrate 3 in the releasing operation. In this case, the corrector 10c obtains an inclination amount (i.e., a correction value) of the substrate stage 4 corresponding to the separation force Fz′ and the distance L. The control unit controls the inclination of the imprint head 7 based on the inclination amount obtained by the corrector 10c. Alternatively, it is feasible to use a value changed by multiplying a correction value obtained based on information indicating a relative positional deviation relationship corresponding to the imprint force Fz and the distance L with a coefficient corresponding to a difference between the imprint force Fz and the separation force Fz′. For example, the separation force Fz′ can be obtained by multiplying a signal value to be supplied to the mold drive unit 7b with a thrust constant indicating a force that the mold drive unit 7b generates when a unit amount of signal value is supplied. Further, if a sensor (e.g., a force sensor, a load cell, or a strain gauge) is provided to detect a force generated by the mold drive unit 7b, it is feasible to obtain the separation force Fz′ based on a detection result obtained by the sensor.

As mentioned above, the imprinting apparatus according to the second exemplary embodiment controls the relative inclination between the mold 6 and the substrate 3 based on the separation force Fz′ and the distance L in the process for separating the mold 6 from the hardened imprint material 11. If the separation force is constant, the relative inclination of the mold 6 and the substrate 3 can be controlled based on the distance L. Therefore, it is feasible to reduce the force acting in such a way as to damage the pattern that may occur when the hardened imprint material 11 is separated from the mold 6.

A third exemplary embodiment will be described in detail below. In the imprinting apparatus 100 according to the above-mentioned exemplary embodiment, the mold 6 inclines relative to the substrate 3 because the applied imprint force inclines the substrate stage 4 when the mold 6 is brought into contact with the imprint material 11. When the imprint force is removed after causing the mold 6 to contact the imprint material 11, the inclination of the substrate stage returns to the original (i.e., parallel) state. However, in a state where the pattern region 6a of the mold 6 is in contact with the imprint material, the viscoelasticity of the imprint material causes a reaction force acting on the pattern region 6a in a direction opposed to the imprint force. The force acting due to the viscoelasticity of the imprint material causes the pattern region 6a of the mold 6 to deform. Therefore, there is a risk of deteriorating the accuracy in the pattern shape (i.e., distortion) of the hardened imprint material.

Further, when the pattern region 6a of the mold 6 is partly brought into contact with the imprint material located on the substrate in the vicinity of the outer periphery of the substrate 3, the imprint force causes the mold to incline because a reaction force difference is caused between a region of the mold 6 that is opposed to the substrate 3 and another region of the mold 6 that is not opposed to the substrate 3. In this case, a force acts on the pattern region 6a due to the viscoelasticity of the imprint material 11 when the imprint force is removed. Therefore, a problem may arise that the distortion of the pattern shape deteriorates. In view of the foregoing, the imprinting apparatus according to the third exemplary embodiment corrects the shape of the pattern region after completing the imprinting operation, in such a way as to reduce the deformation of the pattern region 6a that may occur due to the viscoelasticity of the imprint material.

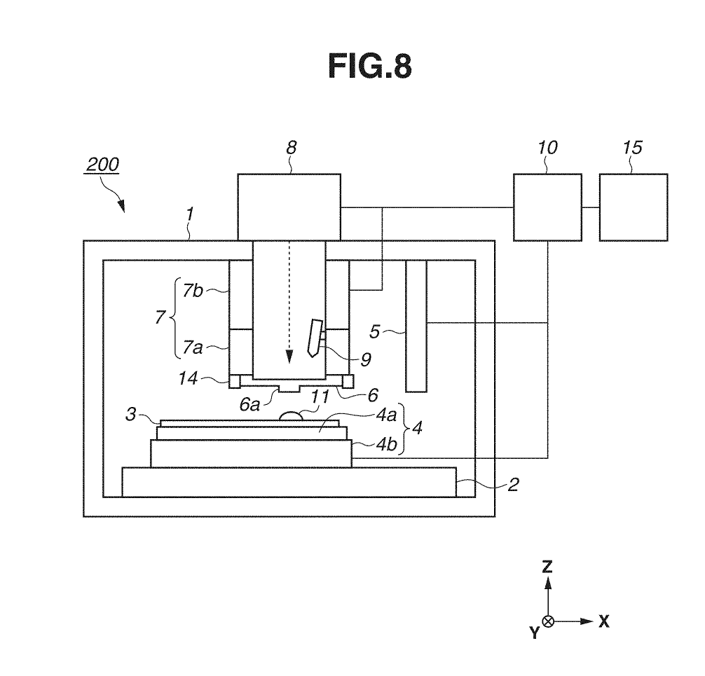

FIG. 8 illustrates an imprinting apparatus 200 according to the third exemplary embodiment. Each member or component similar to that of the imprinting apparatus 100 illustrated in FIGS. 1A and 1B is denoted by the same reference number and redundant description thereof will be avoided. Further, the mold shape correction unit 14 is located along an outer periphery of the mold 6. The pattern region 6a deforms when the mold shape correction unit 14 applies a force to the outer periphery (i.e., side surface) of the mold 6. By causing the pattern region 6a to deform, the imprinting apparatus 200 can correct the magnification difference or shape difference between the pattern region 6a and the pattern region (i.e., the target shot region 3a) formed beforehand on the substrate. The measurement unit 9 can measure the shape difference between the pattern region 6a and the target shot region 3a by detecting the alignment mark formed on the mold 6 (i.e., the pattern region 6a) and the alignment mark provided on the substrate 3 (i.e., the shot region 3a).

As illustrated in FIGS. 4A and 4B, if the relative inclination between the mold 6 and the target shot region 3a is eliminated (see FIG. 4A) when the imprint force is removed after completing the imprinting operation (FIG. 4B), a force is applied to the pattern region 6a due to the viscoelasticity of the imprint material 11. Therefore, the shape of the pattern region 6a may deform into a bow shape and the distortion may reduce. The deformation size of the pattern region 6a is variable depending on the inclination amount of the substrate stage when the mold 6 is brought into contact with the imprint material 11. In the following description, it is assumed that the shape of the pattern region 6a is identical to the shape of the target shot region 3a in a state where no force is applied.

The inclination amount of the substrate stage 4 caused by the imprint force can be roughly predicted with reference to the magnitude of the imprint force and the distance from the reference position to the position where the target shot region 3a is located. If the inclination amount between the mold 6 and the substrate 3 can be predicted with reference to the imprint force and the position of the target shot region, it is feasible to predict the size of deformation of the pattern region 6a that may occur after the imprinting operation due to the viscoelasticity of the imprint material 11. In other words, there is a correlation between the inclination amount and the force acting on the pattern region 6a due to the viscoelasticity of the imprint material 11. Further, there is a correlation between the deformation size of the pattern region 6a and the force acting on the pattern region 6a due to the viscoelasticity of the imprint material 11. Accordingly, predicting the deformation of the pattern region 6a that may occur due to the viscoelasticity of the imprint material is feasible with reference to the magnitude of the imprint force and the horizontal position of the target shot region 3a in the substrate 3 (i.e., the distance from reference position).

If the deformation of the pattern region 6a occurring after the imprinting operation can be predicted, the imprinting apparatus can control the mold shape correction unit 14 to correct the shape of the pattern region 6a in step S104 of the imprint processing sequence illustrated in FIG. 3. The imprinting apparatus 200 according to the present exemplary embodiment can perform correction processing in such a way as to cancel the deformation of the pattern region that may occur due to the viscoelasticity of the imprint material 11.

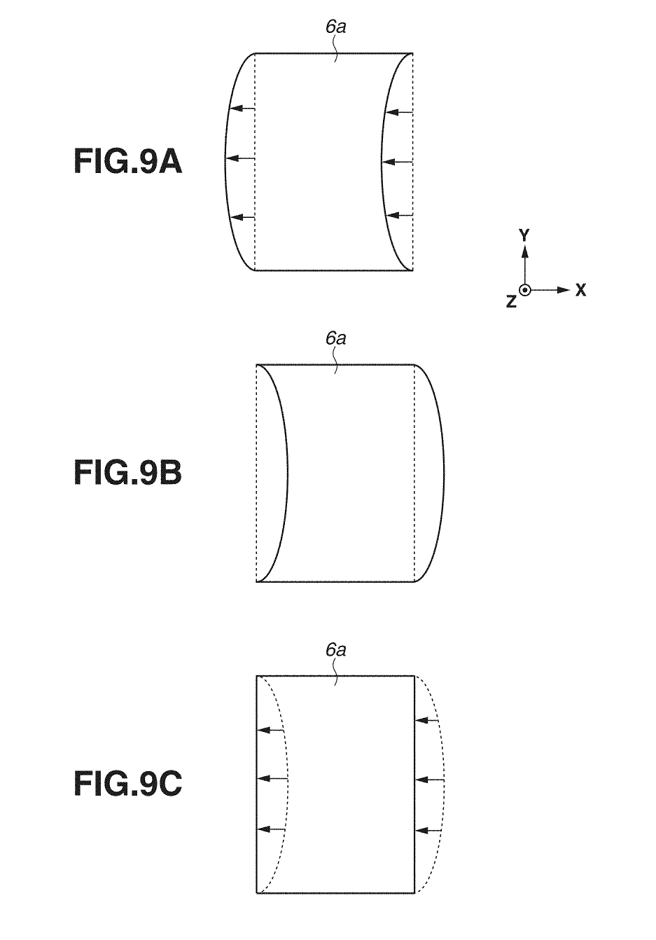

FIGS. 9A, 9B, and 9C each schematically illustrate the shape correction (i.e., distortion correction) that can be performed by the imprinting apparatus 200 according to the third exemplary embodiment. For example, it is assumed that the pattern region 6a deforms from a rectangular shape indicated by a dotted line to a bow shape (protruding in the −X direction) indicated by a solid line due to the viscoelasticity of the imprint material 11 as illustrated in FIG. 9A, after the imprinting operation, if the correction according to the third exemplary embodiment is not performed. The imprinting apparatus 200 drives the mold shape correction unit 14 to deform the shape of the pattern region 6a into a bow shape (protruding in the +X direction) as indicated by a solid line in FIG. 9B, before the mold 6 is brought into contact with the imprint material 11. The shape illustrated in FIG. 9B is a bow shape protruding in a direction opposed to a direction indicated by the arrows illustrated in FIG. 9A. Through the above-mentioned operation, the pattern region 6a deforms from a bow shape indicated by a dotted line to a rectangular shape (i.e., a desired shape) indicated by a solid line in FIG. 9C, after the imprinting operation, due to the viscoelasticity of the imprint material 11.

Further, the imprinting apparatus 200 according to the third exemplary embodiment includes a correction amount prediction unit 15 configured to predict a deformation amount (i.e., a shape correction amount) of the pattern region 6a of the mold 6 caused by the mold shape correction unit 14. The correction amount prediction unit 15 is connected to the control unit 10. In the deformation of the pattern region 6a, the correction amount prediction unit 15 acquires imprint force information and positional information about the target shot region 3a, in which a pattern should be formed, from the control unit 10. Based on the acquired information, the correction amount prediction unit 15 calculates a shape correction amount of the pattern region 6a capable of cancelling the deformation of the pattern region 6a that may occur due to the viscoelasticity of the imprint material 11 and transmits the calculated shape correction amount to the control unit 10. The control unit 10 drives the mold shape correction unit 14 based on the shape correction amount calculated by the correction amount prediction unit 15 to cause the pattern region 6a of the mold 6 to deform. Causing the mold 6 to deform in the process of forming a pattern on the substrate 3 as mentioned above is useful to reduce the magnification difference and the shape difference between the pattern region 6a and the target shot region 3a after the imprinting operation. It is assumed that the correlation between the shape correction amount and the information acquired by the correction amount prediction unit 15 can be obtained beforehand through experiments and simulations.

In the third exemplary embodiment, the imprinting apparatus 200 performs the processing for correcting the shape of the pattern region 6a before the contact operation in step S103 of the operation sequence illustrated in FIG. 3. Alternatively, the imprinting apparatus 200 can perform the above-mentioned shape correction operation after the contact operation in step S103 and before the imprint material hardening operation in step S105.

Further, if a correction table is prepared beforehand and available to correction of the shape of the pattern region 6a, the correction amount prediction unit 15 can be configured to refer to the correction table in the process for driving of the mold shape correction unit 14. Further, an appropriate input unit (not illustrated) can be connected to the control unit 10 to enable a user to input a shape correction amount or a correction table.

The above-mentioned imprinting apparatus 200 corrects the magnification difference and the shape difference between the pattern region 6a and the target shot region 3a by correcting the shape of the pattern region 6a. However, the imprinting apparatus 200 can be configured to correct the magnification difference and the shape difference by causing the target shot region 3a to deform. For example, heating the substrate 3 is useful to change the shape of the target shot region 3a in such a way as to fit with the shape of the pattern region 6a deformed due to the viscoelasticity of the imprint material. In this respect, the imprinting apparatus 200 can include a heat source, i.e., a substrate shape correction unit (not illustrated), which can heat the substrate. Adjusting a distribution of heat added to the target shot region 3a is useful in that a complicated (i.e., higher order) shape correction can be realized, compared to a case where the mold shape correction unit is employed. Using both of the mold shape correction unit and the substrate shape correction unit is useful in correcting the magnification difference and shape difference between the pattern region 6a and the target shot region 3a.

### <Article Manufacturing Method>

An article manufacturing method according to an exemplary embodiment of the present invention is preferably employable, for example, in manufacturing a micro device (e.g., a semiconductor device), an element having a fine structure, or an optical member (e.g., a microlens array). The article manufacturing method according to the present exemplary embodiment includes a process for causing the above-mentioned imprinting apparatus to form a desired pattern of an imprint material supplied to a substrate (i.e., a process for performing imprint processing on a substrate) and a process for adequately fabricating the substrate on which the pattern is formed through the above-mentioned process. The above-mentioned manufacturing method can include any other conventionally known processes (e.g., oxidization, film formation, deposition, doping, flattening, etching, resist stripping, dicing, bonding, and packaging). The article manufacturing method according to the present exemplary embodiment is excellent in at least one of article performance, quality, productivity, and production cost, compared to the conventional method.

The present invention is not limited to the above-mentioned preferred exemplary embodiments and can be appropriately changed or modified in various ways within the scope of the invention.

While aspects of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-038127, filed Feb. 29, 2016, which is hereby incorporated by reference herein in its entirety.

What is claimed is:

1. An imprinting apparatus that can form a pattern of an imprint material supplied to a substrate with a mold, the imprinting apparatus comprising:
a substrate holding unit configured to hold the substrate;
a mold holding unit configured to hold the mold; and
a control unit configured to control the mold holding unit that changes an inclination of the mold while the mold is kept in contact with the imprint material based on a position in a surface direction of the substrate where the mold contacts the imprint material, in such a way as to reduce a relative inclination between the mold and the substrate that may occur if the substrate holding unit inclines in a process for bringing the mold into contact with the imprint material.

2. The imprinting apparatus according to claim 1, wherein when the mold is brought into contact with the imprint material, the control unit controls the relative inclination between the mold and the substrate based on a force applied to the mold and the substrate in the process for bringing the mold into contact the imprint material.

3. The imprinting apparatus according to claim 1, wherein the control unit drives the mold holding unit that holds the mold in such a way as to incline the mold relative to the surface of the substrate.

4. The imprinting apparatus according to claim 1, wherein the control unit drives the substrate holding unit in such a way as to incline the surface of the substrate relative to the mold.

5. The imprinting apparatus according to claim 1, further comprising a substrate measurement unit configured to measure an inclination of the substrate by measuring a height of the substrate,
wherein the control of the control unit is performed based on a measurement result obtained by the substrate measurement unit.

6. The imprinting apparatus according to claim 5, wherein the substrate measurement unit measures an inclination amount of the substrate holding unit in the process for bringing the mold into contact with the imprint material beforehand for each of a plurality of shot regions on the substrate where a pattern is formed, and the control unit controls the relative inclination between the mold and the substrate when the mold is brought into contact with the imprint material based on the inclination amount measured beforehand.

7. The imprinting apparatus according to claim 1, further comprising a mold measurement unit configured to measure the inclination of the mold by measuring a height of the mold,
wherein the control of the control unit is performed with reference to a measurement result obtained by the mold measurement unit.

8. The imprinting apparatus according to claim 1, wherein the control by the control unit is performed with reference to a force applied to the mold and the substrate in the process for brining the mold into contact with the imprint material and a distance from a reference position of the substrate to a position of the substrate where the mold contacts the imprint material.

9. An imprinting apparatus that can form a pattern of an imprint material supplied to a substrate with a mold, the imprinting apparatus comprising:
a substrate holding unit configured to hold the substrate;
a mold holding unit configured to hold the mold;
a substrate measurement unit configured to measure an inclination of the substrate holding unit; and
a control unit configured to control the mold holding unit that changes an inclination of the mold while the mold is kept in contact with the imprint material based on a measurement result obtained by the substrate measurement unit, in such a way as to reduce a relative inclination between the mold and the substrate that may occur if the substrate holding unit inclines in a process for bringing the mold into contact with the imprint material.

10. An imprinting apparatus that can form a pattern of an imprint material supplied to a substrate with a mold, the imprinting apparatus comprising:
a substrate holding unit configured to hold the substrate;
a mold holding unit configured to hold the mold; and
a control unit configured to control a relative inclination between the mold and the substrate that may occur when the mold is separated from the imprint material, based on a position in a surface direction of the substrate where the mold contacts the imprint material, in such a way as to reduce the relative inclination between the mold and the substrate that may occur if the substrate holding unit inclines in a process for separating the mold from the imprint material.

11. An imprinting apparatus that can form a pattern of an imprint material supplied to a substrate with a mold, the imprinting apparatus comprising:
a substrate holding unit configured to hold the substrate;
a mold holding unit configured to hold the mold;
a substrate measurement unit configured to measure an inclination of the substrate holding unit; and
a control unit configured to control a relative inclination between the mold and the substrate that may occur when the substrate holding unit inclines, based on a measurement result obtained by the substrate measurement unit, when the mold is separated from the imprint material, in such a way as to reduce the relative inclination between the mold and the substrate that may occur if the substrate holding unit includes in a process for separating the mold from the imprint material.

12. An article manufacturing method comprising:
forming a pattern on a substrate with an imprint apparatus; and
fabricating the substrate on which the pattern is formed,
wherein the imprinting apparatus can form a pattern of an imprint material supplied to the substrate with a mold, the imprinting apparatus includes:
a substrate holding unit configured to hold the substrate;
a mold holding unit configured to hold the mold; and
a control unit configured to control the mold holding unit that changes an inclination of the mold while the mold is kept in contact with the imprint material based on a position in a surface direction of the substrate where the mold contacts the imprint material, in such a way as to reduce a relative inclination between the mold and the substrate that may occur if the substrate holding unit inclines in a process for bringing the mold into contact with the imprint material.
